(19) United States
(12) Patent Application Publication
(10) Pub. No.: US 2006/0138487 A1
(43) Pub. Date: Jun. 29, 2006

(54) CMOS image sensor and method for fabricating the same

(76) Inventor: Young Rok Kim, Seoul (KR)

Correspondence Address: MCKENNA LONG & ALDRIDGE LLP;Song K. Jung, 1900 K Street, N.W., Washington, DC, 20006, US

(21) Appl. No.: 11/315,158

(22) Filed: Dec. 23, 2005

(30) Foreign Application Priority Data
Dec. 24, 2004 (KR) 10-2004-0112063

(51) Int. Cl. H01L 31/113

(52) U.S. Cl. 257/292

(57) ABSTRACT

A CMOS image sensor and a method for fabricating the same are disclosed, in which color filter layers are formed after microlenses are formed, to simplify process steps and maximize transmission efficiency of light, thereby improving performance of the image sensor. The CMOS image sensor includes a plurality of photodiodes formed in a semiconductor substrate, microlenses formed over the semiconductor substrate corresponding to the photodiodes, and color filter layers formed on the microlenses.

### CROSS REFERENCE TO RELATED APPLICATION

This application claims the benefit of the Korean Patent Application No. 10-2004-0112063, filed on Dec. 24, 2004, which is hereby incorporated by reference for all purposes as if fully set forth herein.

### BACKGROUND OF THE INVENTION

1. Field of the Invention

The present invention relates to an image sensor, and more particularly, to a complementary metal-oxide semiconductor (CMOS) image sensor and a method for fabricating the same, in which loss of incident light to photodiodes is suppressed, process steps are simplified, and transmission efficiency of light is increased.

2. Discussion of the Related Art

Generally, an image sensor is a semiconductor device that converts optical images to electrical signals. The image sensor is classified into a charge coupled device (CCD) image sensor and a CMOS image sensor.

The CMOS image sensor includes a photodiode area sensing light and a CMOS logic circuit area processing the sensed light to generate electrical signals. If light-receiving amount of the photodiode is great, the image sensor has excellent photosensitivity characteristics.

To enhance photosensitivity, it is necessary to increase a fill factor of an area occupied by the photodiode among the whole area of the image sensor. Alternatively, it is necessary to change a path of incident light to an area other than the photodiode so as to concentrate light onto the photodiode.

To concentrate light onto the photodiode, a microlens is generally used. A convex microlens made of a material having good light transmittance is formed on the photodiode to refract a path of incident light, thereby irradiating more light to the photodiode.

Hereinafter, a related art CMOS image sensor will be described with reference to the accompanying drawings.

FIG. 1 is a sectional view illustrating a related art CMOS image sensor.

As shown in FIG. 1, the related art CMOS image sensor includes at least one or more photodiodes 11 formed in a semiconductor substrate (not shown) to generate charges in response to incident light, a dielectric interlayer 12 formed on an entire surface of the semiconductor substrate including the photodiodes 11, a passivation layer 13 formed on the dielectric interlayer 12, a first planarization layer 14 formed on the passivation layer 13, R/G/B color filter layers 15 formed on the first planarization layer 14 to respectively pass through light of specific wavelengths, a second planarization layer 16 formed on the entire surface including the color filter layers 15, and convex microlenses 17 having a certain curvature formed on the second planarization layer 16 to pass through their corresponding color filter layers 15, thereby concentrating light to the photodiodes 11.

Although not shown, the CMOS image sensor further includes a light-shielding layer formed in the dielectric interlayer 12 to prevent light from entering a portion other than the photodiodes 11.

Instead of the photodiode, a photogate type device may be used as a device for sensing light.

The curvature and the thickness of the microlenses 17 are determined considering various factors such as a focal point of condensed light. A resin such as polymer is generally used as a material of the microlenses 17. The microlenses 17 are formed by deposition, patterning and reflow processes.

The optimal size and thickness and the curvature radius of the microlenses 17 should be determined by size, position and shape of a unit pixel, a thickness of the photodiode, and height, position and size of the light-shielding layer.

A photoresist is generally used as the microlenses 17 whose curvature and height are determined considering various factors such as a focal point of the light. The photoresist is coated and then patterned by exposing and developing processes to form a photoresist pattern. The photoresist pattern is then completed by a reflow process.

The pattern profile is varied depending on focus of the photoresist.

For example, process conditions are varied depending on a condition of a sub-layer. Therefore, a profile of the microlenses is also varied.

In the process for fabricating the aforementioned related art CMOS image sensor, the microlenses 17 formed to improve concentration efficiency of light serves as a main factor that determines characteristics of the image sensor.

The microlenses 17 serves to concentrate more light onto the photodiodes 11 through the respective color filter layers 15 when the light is irradiated.

The incident light to the image sensor is concentrated by the microlenses 17 and filtered by the color filter layers 15. The light then enters the photodiodes 111 corresponding to the color filter layers 15.

The light-shielding layer serves to prevent the incident light from getting out of its path.

When the related art CMOS image sensor is fabricated, the first and second planarization layers 14 and 16 are formed and the color filter layers 15 and the microlenses 17 are additionally formed thereon. However, in such instances, the transmission efficiency of the light is deteriorated. This could deteriorate performance of the CMOS image sensor.

### SUMMARY OF THE INVENTION

Accordingly, the present invention is directed to a CMOS image sensor and a method for fabricating the same that substantially obviates one or more problems due to limitations and disadvantages of the related art.

An advantage of the present invention is that it provides a CMOS image sensor and a method for fabricating the same in which color filter layers are formed after microlenses are formed, to simplify process steps and maximize transmission efficiency of light, thereby improving performance of the image sensor.

Additional advantages and features of the invention will be set forth in part in the description which follows, and will be apparent from the description, or may be learned by practice of the invention. These and other advantages of the invention may be realized and attained by the structure particularly pointed out in the written description and claims hereof as well as the appended drawings.

To achieve these and other advantages and in accordance with the purpose of the invention, as embodied and broadly described herein, a CMOS image sensor according to the present invention includes a plurality of photodiodes formed in a semiconductor substrate, microlenses formed over the semiconductor substrate corresponding to the photodiodes, and color filter layers formed on the microlenses.

In another aspect of the present invention, a method for fabricating a CMOS image sensor includes forming a plurality of photodiodes in a semiconductor substrate, forming microlenses over the semiconductor substrate corresponding to the photodiodes, and forming color filter layers on the microlenses.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principle of the invention.

In the drawings:

FIG. 1 is a structural sectional view illustrating a related art CMOS image sensor;

FIG. 2 is a structural sectional view illustrating a CMOS image sensor according to an exemplary embodiment of the present invention; and

FIG. 3A to FIG. 3C are sectional views of a CMOS image sensor fabricated using a method according to an exemplary embodiment the present invention.

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or like parts.

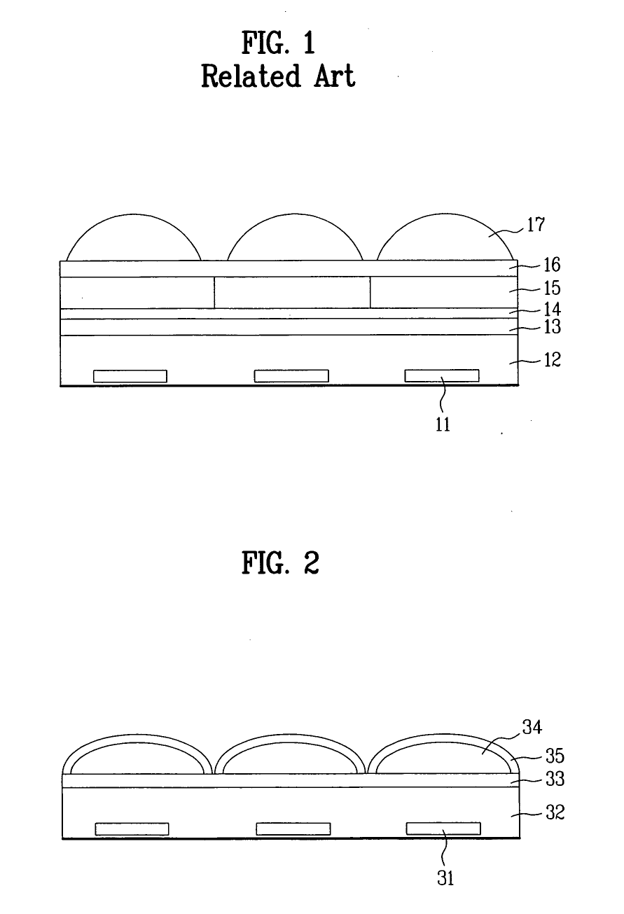

FIG. 2 is a structural sectional view illustrating a CMOS image sensor according to an embodiment of the present invention.

As shown in FIG. 2, the CMOS image sensor according to an embodiment of the present invention includes at least one or more photodiodes 31 formed in a semiconductor substrate (not shown) to generate charges in response to incident light, a dielectric interlayer 32 formed on an entire surface of the semiconductor substrate including the photodiodes 31, a passivation layer 33 formed on the dielectric interlayer 32, microlenses 34 formed on the passivation layer 33 to correspond to the photodiodes 31, and color filter layers 35 formed on the microlenses 34.

In an exemplary embodiment of the present invention, the passivation layer 33 is formed in such a manner that an oxide film and a nitride film are sequentially deposited. The color filter layers 35 are formed to surround the microlenses 34.

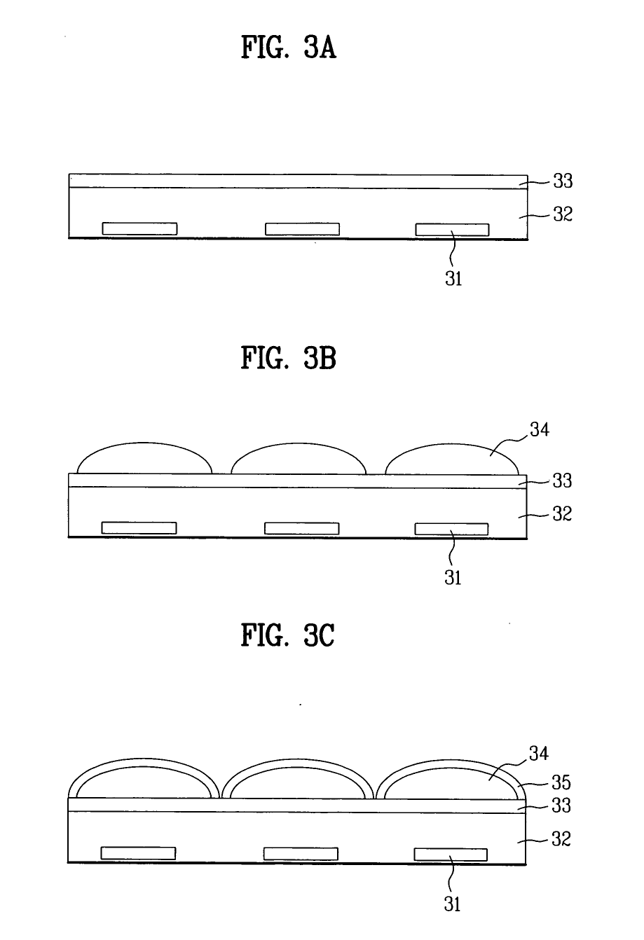

FIG. 3A to FIG. 3C are sectional views of a CMOS image sensor illustrating a method for fabricating the CMOS image sensor according to an exemplary embodiment of the present invention.

As shown in FIG. 3A, the dielectric interlayer 32 is formed on the entire surface of the semiconductor substrate in which the photodiodes 31 generating charges in response to the incident light are formed. Although not shown, a plurality of dielectric interlayers 32 may be formed to form a light-shielding layer between the dielectric interlayers 32, thereby preventing the light from entering portions other than the photodiodes 31.

Subsequently, the passivation layer 33 comprised of, for example, an oxide film and a nitride film deposited sequentially is formed on the dielectric interlayer 32 to protect the image sensor from water and scratch.

As shown in FIG. 3B, a material layer (not shown) for the microlenses is coated on the passivation layer 33 by using either photoresist or oxide film such as SiON. Subsequently, the material layer for the microlenses is selectively patterned by exposing and developing processes, so that microlens patterns are formed to correspond to the respective photodiodes 31. The respective microlens patterns undergo a reflow process at a predetermined temperature to form hemispheric lenses 34.

As shown in FIG. 3C, a salt resist is coated on the respective microlenses 34 and then patterned to form the color filter layers 35 that filter light at respective wavelengths. In this manner, the color filter layers may be formed to surround the microlenses.

As described above, the CMOS image sensor and the method for fabricating the same according to the present invention have the following advantages.

First, since no planarization layer is required before the color filter layers and the microlenses are formed, it is possible to reduce light loss. As a result, it is possible to improve intensity of the light transmitted to a logic circuit.

Second, the microlenses are formed below the color filter layers, it is possible to reduce the transmission distance of the light.

Finally, since the process steps are simplified and the transmission distance of the light is reduced because of no planarization layer, it is possible to improve productivity.

It will be apparent to those skilled in the art that various modifications and variations can be made in the present invention without departing from the spirit or scope of the inventions. Thus, it is intended that the present invention cover the modifications and variations of this invention provided they come within the scope of the appended claims and their equivalents.

What is claimed is:

1. A CMOS image sensor comprising:
a semiconductor substrate a plurality of photodiodes formed in the semiconductor substrate;
microlenses formed over the semiconductor substrate corresponding to the photodiodes; and
color filter layers formed on the microlenses.

2. The CMOS image sensor according to claim 1, wherein the color filter layers are formed to surround the microlenses.

3. The CMOS image sensor according to claim 1, further comprising a dielectric interlayer formed on the semiconductor substrate and a passivation layer formed on the dielectric interlayer, wherein the microlenses are formed on the passivation layer.

4. The CMOS image sensor according to claim 3, wherein the passivation layer includes an oxide film formed on the dielectric interlayer and a nitride film formed on the oxide film.

5. The CMOS image sensor according to claim 1, wherein the microlenses are formed of photoresist.

6. The CMOS image sensor according to claim 1, wherein the microlenses are formed of oxide film.

7. A method for fabricating a CMOS image sensor comprising:
forming a plurality of photodiodes in a semiconductor substrate;
forming microlenses over the semiconductor substrate corresponding to the photodiodes; and
forming color filter layers on the microlenses.

8. The method according to claim 7, wherein the color filter layers are formed to surround the microlenses.

9. The method according to claim 7, further comprising forming a dielectric interlayer on the semiconductor substrate and forming a passivation layer on the dielectric interlayer, before forming the microlenses.

10. The method according to claim 9, wherein the step of forming the passivation layer includes forming an oxide film on the dielectric interlayer and forming a nitride film on the oxide film.

11. The method according to claim 7, wherein the microlenses are formed of photoresist.

12. The method according to claim 7, wherein the microlenses are formed of oxide film.
